(19) United States
(12) Patent Application Publication
(10) Pub. No.: US 2025/0348009 A1
(43) Pub. Date: Nov. 13, 2025

(54) METROLOGY METHOD AND ASSOCIATED METROLOGY DEVICE

(71) Applicant: ASML Netherlands B.V., Veldhoven (NL)

(72) Inventors: Victor Emanuel CALADO, Rotterdam (NL); Simon Gijsbert Josephus MATHIJSSEN, Rosmalen (NL); Amanda Elizabeth ANDERSON, Valkenswaard (NL)

(73) Assignee: ASML Netherlands B.V., Veldhoven (NL)

(21) Appl. No.: 18/869,667

(22) PCT Filed: Jul. 19, 2023
(86) PCT No.: PCT/EP2023/070048

§ 371 Date: Nov. 26, 2024

(30) Foreign Application Priority Data
Aug. 8, 2022 (EP) 22189256.5

(51) Int. Cl. G03F 7/00

(52) U.S. Cl. CPC G03F 7/706831; G03F 7/70633; G03F 7/706839; G03F 7/706851

(57) ABSTRACT

Disclosed is a metrology method. The method comprises obtaining measurement data relating to measurement of at least one target using two or more different illumination profiles; and a respective parameter of interest value for a parameter of interest for each of said two or more different illumination profiles. The method described determining, from said measurement data, a respective measurement parameter deviation value for each of said two or more different illumination profiles, said measurement parameter deviation value describing a deviation in a measurement parameter with respect to a measurement parameter value attributed to a region of interest of said target or a sub-target thereof; determining a relationship for the target between the parameter of interest values and the measurement parameter deviation values; and determining one or both of a corrected parameter of interest value and a preferred illumination profile from said relationship.

### CROSS-REFERENCE TO RELATED APPLICATIONS

This application claims priority of EP application 22189256.5 which was filed on 8 Aug. 2022 and which is incorporated herein in its entirety by reference.

### FIELD

The present invention relates to a metrology method and device which may, for example, be used for determining a characteristic of structures on a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

In lithographic processes, it is desirable to make frequently measurements of the structures created, e.g., for process control and verification. Various tools for making such measurements are known, including scanning electron microscopes or various forms of metrology apparatuses, such as scatterometers. A general term to refer to such tools may be metrology apparatuses or inspection apparatuses.

In some metrology methods, the measured target is “overfilled”; i.e., the metrology target is smaller than the measurement spot. This has benefits over more conventional “underfilled” measurements, where the measurement spot is smaller than the target. Overfilled metrology enables smaller targets, and also enables simultaneous acquisition of a number of different sub-targets or target pads. It also enables algorithms to be used which enable selection of particular target areas (e.g., pixel mapping).

However, overfilled metrology is susceptible to edge effects. Edge effects often manifest as brighter (or less bright) regions along one or more edges of one or more of the pads; these brighter regions also affect the region of interest of the sub-target being considered.

It is desirable to mitigate for such edge effects.

### SUMMARY

Embodiments of the invention are disclosed in the claims and in the detailed description.

In a first aspect of the invention there is provided a metrology method comprising: obtaining measurement data relating to measurement of at least one target using two or more different illumination profiles; determining, from said measurement data, a respective parameter of interest value for a parameter of interest for each of said two or more different illumination profiles, determining, from said measurement data, a respective measurement parameter deviation value for each of said two or more different illumination profiles, said measurement parameter deviation value describing a deviation in a measurement parameter with respect to a measurement parameter value attributed to a region of interest of said target or a sub-target thereof; determining a relationship for the target between the parameter of interest values and the measurement parameter deviation values; and determining one or both of a corrected parameter of interest value and a preferred illumination profile from said relationship.

According to a second aspect of the present invention there is provided a computer program comprising program instructions operable to perform the method of the first aspect, when run on a suitable apparatus.

The invention yet further provides a processing arrangement and metrology device comprising the computer program of the second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is a schematic illustration of a scatterometry apparatus;

FIG. 5 comprises (a) a schematic diagram of a dark field scatterometer for use in measuring targets according to embodiments of the invention using a first pair of illumination apertures, (b) a detail of diffraction spectrum of a target grating for a given direction of illumination (c) a second pair of illumination apertures providing further illumination modes in using the scatterometer for diffraction based overlay measurements (d) a third pair of illumination apertures combining the first and second pair of apertures; and

FIG. 6 is a flow diagram of a metrology method according to an embodiment.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

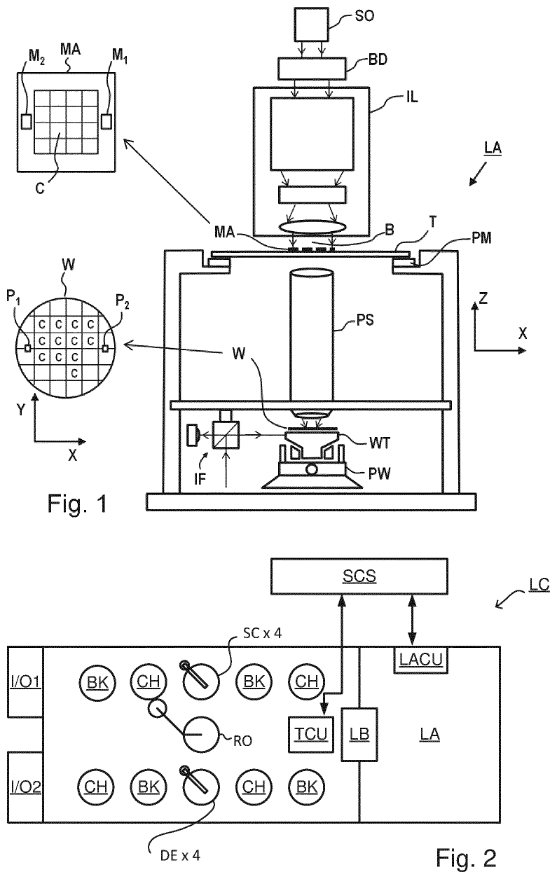

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

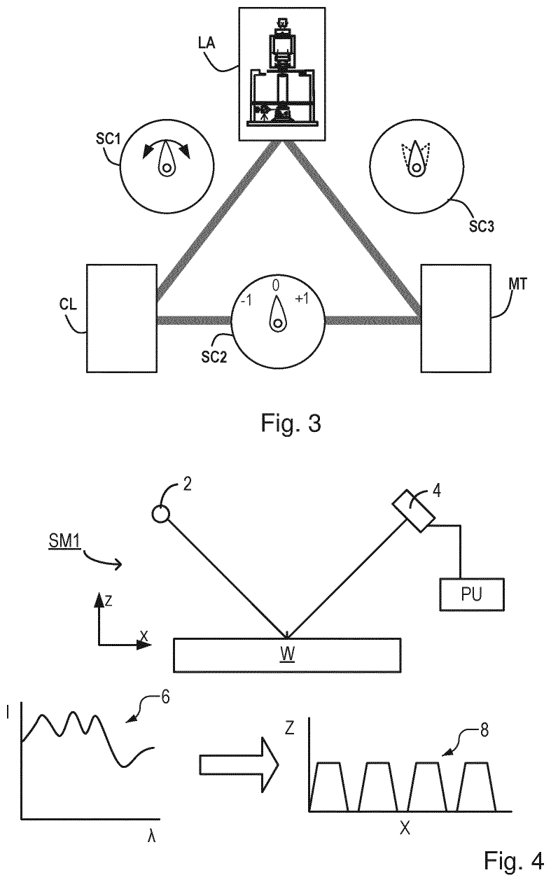

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MET (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MET may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Various tools for making such measurements are known, including scanning electron microscopes or various forms of metrology apparatuses, such as scatterometers. Examples of known scatterometers often rely on provision of dedicated metrology targets, such as underfilled targets (a target, in the form of a simple grating or overlapping gratings in different layers, that is large enough that a measurement beam generates a spot that is smaller than the grating) or overfilled targets (whereby the illumination spot partially or completely contains the target). Further, the use of metrology tools, for example an angular resolved scatterometer illuminating an underfilled target, such as a grating, allows the use of so-called reconstruction methods where the properties of the grating can be calculated by simulating interaction of scattered radiation with a mathematical model of the target structure and comparing the simulation results with those of a measurement. Parameters of the model are adjusted until the simulated interaction produces a diffraction pattern similar to that observed from the real target.

Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers can measure in one image multiple targets from multiple gratings using light from soft x-ray and visible to near-IR wave range.

A metrology apparatus, such as a scatterometer, is depicted in FIG. 4. It comprises a broadband (white light) radiation projector 2 which projects radiation 5 onto a substrate W. The reflected or scattered radiation 10 is passed to a spectrometer detector 4, which measures a spectrum 6 (i.e. a measurement of intensity I as a function of wavelength λ) of the specular reflected radiation 10. From this data, the structure or profile 8 giving rise to the detected spectrum may be reconstructed by processing unit PU, e.g. by Rigorous Coupled Wave Analysis and non-linear regression or by comparison with a library of simulated spectra. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is an ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent applications Ser. No. 11/451,599, 11/708,678, 12/256,780, 12/486,449, 12/920,968, 12/922,587, 13/000,229, 13/033,135, 13/533,110 and 13/891,410 incorporated herein by reference in their entirety.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US 20160161863, incorporated herein by reference in its entirety. Other parameters of interest may be focus and dose. Focus and dose may be determined simultaneously by scatterometry (or alternatively by scanning electron microscopy) as described in US patent application US2011-0249244, incorporated herein by reference in its entirety.

The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

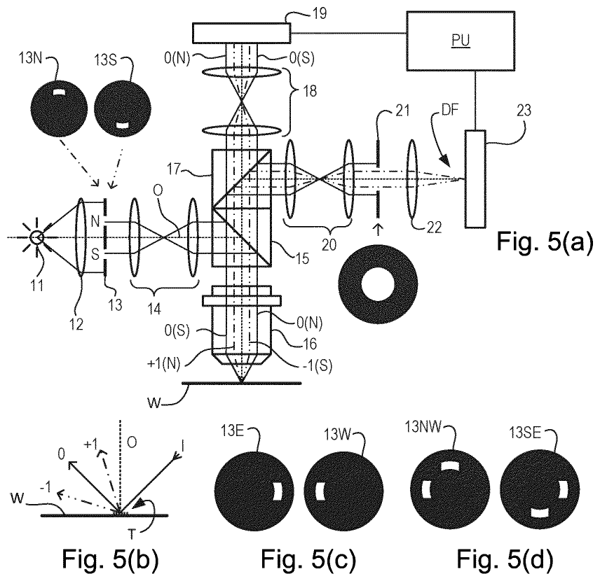

FIG. 5(a) presents an embodiment of a metrology apparatus and, more specifically, a dark field scatterometer. A target T and diffracted rays of measurement radiation used to illuminate the target are illustrated in more detail in FIG. 5(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 5(b), target T is placed with substrate W normal to the optical axis O of objective lens 16. The substrate W may be supported by a support (not shown). A ray of measurement radiation I impinging on target T from an angle off the axis O gives rise to a zeroth order ray (solid line 0) and two first order rays (dot-chain line +1 and double dot-chain line −1). It should be remembered that with an overfilled small target, these rays are just one of many parallel rays covering the area of the substrate including metrology target T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the targets and the illumination angles can be designed or adjusted so that the first order rays entering the objective lens are closely aligned with the central optical axis. The rays illustrated in FIGS. 5(a) and 3(b) are shown somewhat off axis, purely to enable them to be more easily distinguished in the diagram.

At least the 0 and +1 orders diffracted by the target T on substrate W are collected by objective lens 16 and directed back through beam splitter 15. Returning to FIG. 5(a), both the first and second illumination modes are illustrated, by designating diametrically opposite apertures labeled as north (N) and south(S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

The particular forms of aperture plate 13 and field stop 21 shown in FIG. 5 are purely examples. In another embodiment of the invention, on-axis illumination of the targets is used and an aperture stop with an off-axis aperture is used to pass substantially only one first order of diffracted light to the sensor. In yet other embodiments, 2nd, 3rd and higher order beams (not shown in FIG. 5) can be used in measurements, instead of or in addition to the first order beams.

In order to make the measurement radiation adaptable to these different types of measurement, the aperture plate 13 may comprise a number of aperture patterns formed around a disc, which rotates to bring a desired pattern into place. Note that aperture plate 13N or 13S can only be used to measure gratings oriented in one direction (X or Y depending on the set-up). For measurement of an orthogonal grating, rotation of the target through 90° and 270° might be implemented. Different aperture plates are shown in FIGS. 5(c) and (d). The use of these, and numerous other variations and applications of the apparatus are described in prior published applications, mentioned above.

As an alternative to a scatterometer, a metrology device may comprise a holographic microscope such as a digital holographic microscope or digital dark-field holographic microscope. Such as device is disclosed, for example, in WO2021121733A1 which is incorporated herein by reference.

One known metrology method which may be performed using a metrology tool such as illustrated in FIG. 5(a) is known as diffraction based overlay (DBO) or micro-diffraction based overlay (μDBO). Such μDBO techniques use the imaging branch (the branch through detector 23) of the metrology tool, and determine asymmetry in a structure based on an intensity or diffraction efficiency asymmetry or intensity or diffraction efficiency difference between a first diffraction order and a second diffraction order of a pair of complementary pair of diffraction orders (typically a complementary pair of first diffraction orders, i.e., the first diffraction order may comprise the +1 order and the second diffraction order may comprise the −1 order as illustrated in FIG. 5(b)). As such, in this context, the terms “first” and “second” do not refer to a diffraction order number and are simply being used to distinguish the two diffractions orders of a complementary pair, noting that the first and second diffraction orders may be the +2 and −2 diffraction orders or a higher pair of complementary diffraction orders. The zeroth order (specular radiation) is typically blocked or diverted elsewhere (e.g., to another part of the detector for monitoring purposes); it is not used in μDBO metrology. The main “images” used for parameter of interest inference are formed only from higher (e.g., first) diffraction orders. The asymmetry of the structure may be used to infer a parameter of interest such as overlay or focus, depending on the target design.

The measurement parameter (e.g., intensity, amplitude or diffraction efficiency) may be determined from the captured μDBO camera images by finding the target position and integrating a certain region of interest (ROI) within the camera images, e.g., to provide a single value for the measurement parameter for each sub-target. However, a measurement image may show a significant measurement parameter deviation from the average value over the region of interest at one or more edges of one or more sub-targets of an imaged target. This measurement parameter deviation may be referred to as an edge effect. In many cases, it manifests as a region of higher intensity (or related parameter) at the target edge, although it may also manifest as a region of lower intensity. In either case, this edge effect impacts the intensity/measurement parameter within the region of interest, and therefore impacts parameter of interest (e.g., overlay) inference from the measurement parameter. As targets become smaller (e.g., 5 μm square and smaller), the edge effects become more significant and more difficult to deal with using known methods. In addition, edge effect from the surroundings may also present an issue.

Therefore, to address the issue of edge effect, a method is proposed, comprising obtaining measurement data relating to measurement of a target using two or more different illumination profiles; determining a respective parameter of interest value for a parameter of interest for each of said two or more different illumination profiles, determining a respective measurement parameter deviation value for each of said two or more different illumination profiles, said measurement parameter deviation value describing a (e.g., maximum or minimum (extremum)) deviation in a measurement parameter with respect to a measurement parameter value attributed to a region of interest of said target; determining a relationship for the target between the parameter of interest values and the measurement parameter deviation values; and determining one or both of a corrected parameter of interest value and a preferred illumination profile from said relationship.

The method may comprise determining the preferred illumination profile as the illumination profile which minimizes the measurement parameter deviation for the target.

The step of determining a relationship may comprise fitting a (e.g., linear) model relating the parameter of interest values and the measurement parameter deviation values.

The measurement parameter deviation values may be determined from regions of detected measurement images outside of said regions of interest; e.g., at one or more edges of each target or sub-target.

The method may comprise determining the corrected parameter of interest value as the parameter of interest value corresponding to a zero measurement parameter deviation value according to said relationship.

The target may comprise a pair of sub-targets (with at least one of the pair having a deliberate bias such that there is a bias differential between the pairs of sub-targets) for each of one or more measurement directions, with the parameter of interest determined from the pair of sub-targets. As is known, the sub-targets of each pair may comprise biases of equal magnitude and opposite direction. Where the target comprises sub-targets per measurement direction, the method may be performed per measurement direction (e.g., where a measurement direction relates to one of two perpendicular directions of a substrate plane, the sub-targets being typically referred to as the X and Y sub-targets). Where the target comprises two or more sub-targets, the measurement parameter deviation value for each target may optionally comprise the largest magnitude measurement parameter deviation value over the different sub-targets. Another alternatives may comprise using an average of the measurement parameter deviation values over the sub-targets. As such, the sub-target used to determine the actual measurement parameter deviation is not critical.

The method may be performed inline per target; e.g., each target may be illuminated using said two or more different illumination profiles to obtain the measurement data and determine a correction and/or preferred illumination profile for each target.

The number of illumination profiles used per target may be two, more than two, more than three or more than five, for example.

The different illumination profiles may comprise different illumination shapes in an illumination pupil plane, i.e., corresponding to different ranges or groups of illumination angles.

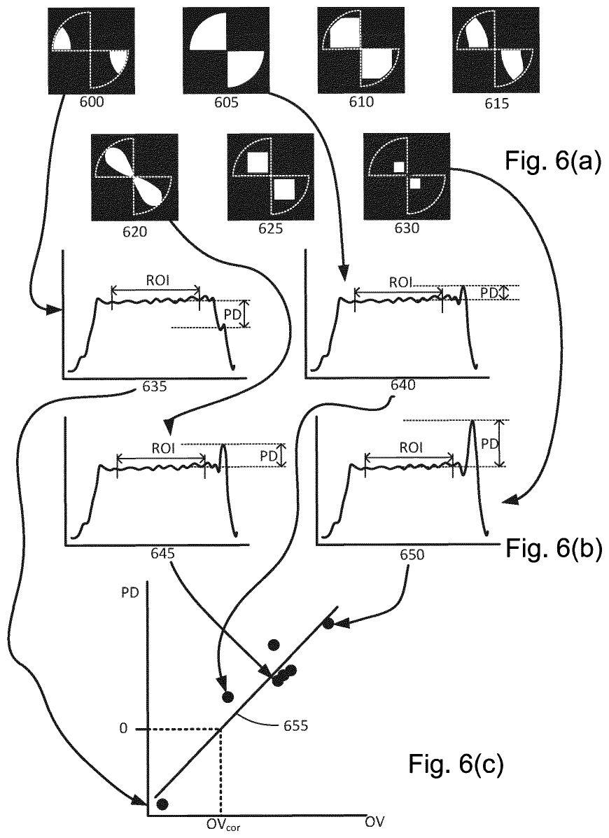

FIG. 6 is a flow diagram illustrating a method according to an embodiment. FIG. 6(a) shows a number of purely exemplary illumination profiles 600-630 or illumination apertures which may be used in the methods disclosed herein. The number of different illumination profiles used and/or their shape may differ from those illustrated. As such, the shape of any of illumination profiles 600-630 may differ significantly in size, shape and/or position within the illumination pupil plane.

FIG. 6(b) shows four plots 635-650 of a measurement parameter (e.g., intensity) against target or sub-target position (here in one dimension) for four of the illumination profiles 600, 605, 620, 630. In each case, a representative (e.g., an average) measurement parameter value is determined over a region of interest ROI within which there is only a small variation of the measurement parameter. Also shown is a measurement parameter deviation value PD which is the difference between a maximum or minimum measurement parameter value and the average value within the ROI, or the maximum or minimum measurement parameter value divided by the average value within the ROI. This step of determining a measurement parameter deviation value PD may be performed for all illumination profiles 600-630.

The method may further comprise determining a measurement of interest value (e.g., overlay value) separately for the measurement data relating to each of the illumination profiles 600-630. This may be done in any known way for calculating the parameter of interest from measurement value data (e.g., intensity data), such as from intensity/measurement parameter asymmetry or the intensity/measurement parameter difference of a pair of complementary diffraction orders (e.g., the +1 order and −1 order).

Because a single overlay value may be determined from two images (e.g., from the +1 order and the −1 order), the measurement parameter deviation value may be determined from either image (or both images, e.g., an average). In an embodiment, the measurement parameter deviation value having the largest magnitude may be chosen. Such an approach may also be used when an overlay value is determined from four images (e.g., from the +1 order and the −1 order from two differently biased sub-targets), e.g., the largest magnitude of the measurement parameter deviation values from the four images may be chosen. This is not essential however.

FIG. 6(c) is a plot of parameter of interest deviation PD against the inferred parameter of interest (e.g., overlay) OV. The plot comprises (in this specific example) seven points, each corresponding to a respective one of the illumination profiles 600-630. A linear regression or model 655 may be fitted to this data. According to this model 655, the overlay (or other parameter of interest) value OVcor corresponding to zero parameter of interest deviation PD may be determined and used as a corrected parameter of interest/overlay value.

Alternatively or in addition, the model 655 may be used to identify a preferred illumination profile, e.g., an illumination profile which corresponds to, is very close to, or is closest to zero for the parameter of interest deviation.

The concepts disclosed herein are disclosed in terms of overlay metrology. However, the methods are not so limited. For example, targets may be formed with a focus based asymmetry (i.e., asymmetry dependent on the actual scanner focus used to expose the target). The methods disclosed herein can equally be applied to focus metrology (e.g., diffraction based focus DBF or micro-diffraction based focus μDBF) based in such targets, in which case the model determined would be of measurement parameter deviation against inferred focus. Similarly, other target types and metrology techniques may be used such as continuous diffraction based overlay (cDBO) targets, and corresponding cDBO measurement techniques.

To measure each target with different illumination profiles, an Illumination Mode Selector (IMS) may be used. An IMS is a known illumination selection method in which different fixed apertures are arranged on an aperture wheel such that they can be selectively switched or rotated into the illumination beam path as required. Faster switching between illumination profiles may be obtained via other illumination technologies, e.g., using programmable illumination such as implemented using grating light valve (GLV) technology such as marketed by Silicon Light Machines (SLM), e.g., as described in U.S. Pat. No. 6,947,613B, or using any suitable spatial light modulation technology (e.g., within an illumination pupil plane) for example. Fast switching between different illumination profiles (and optionally different colors) may be beneficial when performing the proposed method inline, for example. As such, the implementation of the different illumination may be achieved in a number of different ways. The illumination profile may be defined or imposed at an illumination pupil plane (e.g., at plane 13 as illustrated in FIG. 5(a)).

Further embodiments according to the present invention are described in below numbered clauses:

1. A metrology method comprising:
obtaining measurement data relating to measurement of at least one target using two or more different illumination profiles;
determining, from said measurement data, a respective parameter of interest value for a parameter of interest for each of said two or more different illumination profiles,
determining, from said measurement data, a respective measurement parameter deviation value for each of said two or more different illumination profiles, said measurement parameter deviation value describing a deviation in a measurement parameter with respect to a measurement parameter value attributed to a region of interest of said target or a sub-target thereof;
determining a relationship for the target between the parameter of interest values and the measurement parameter deviation values; and
determining one or both of a corrected parameter of interest value and a preferred illumination profile from said relationship.

2. A method according to clause 1, comprising determining the preferred illumination profile as the illumination profile which corresponds to the lowest measurement parameter deviation for the target.

3. A method according to clause 1 or 2, wherein the step of determining a relationship comprises fitting a model relating the parameter of interest values and the measurement parameter deviation values.

4. A method according to clause 3, wherein said model comprises a linear model.

5. A method according to any preceding clause, wherein said measurement parameter deviation value describes an extremum deviation in a measurement parameter with respect to a measurement parameter value attributed to a region of interest of said target or a sub-target thereof.

6. A method according to any preceding clause, comprising determining the corrected parameter of interest value as the parameter of interest value corresponding to a zero measurement parameter deviation value according to said relationship.

7. A method according to any preceding clause, wherein the measurement parameter deviation values are determined from regions of detected measurement images outside of said regions of interest.

8. A method according to any preceding clause, wherein the measurement parameter deviation values are determined from one or more edges of said target or one or more sub-targets thereof.

9. A method according to any preceding clause, wherein the target comprises one or more sub-targets per measurement direction, and the method is performed per measurement direction to obtain a corrected parameter of interest value and/or a preferred illumination profile per measurement direction.

10. A method according to any preceding clause, wherein the number of illumination profiles used per target is more than three.

11. A method according to any preceding clause, wherein the number of illumination profiles used per target is more than five.

12. A method according to any preceding clause, wherein said measurement parameter value attributed to a region of interest of said target or a sub-target thereof comprises an average measurement parameter value for the region of interest.

13. A method according to any preceding clause, wherein said measurement parameter is intensity, diffraction efficiency or amplitude.

14. A method according to any preceding clause, wherein said parameter of interest is overlay or focus.

15. A method according to any preceding clause, wherein said measurement parameter deviation for the target comprises the measurement parameter deviation value having the greatest magnitude over different sub-targets of said target and/or different diffraction orders scattered by the targets.

16. A method according to any preceding clause, comprising measuring said at least one target to obtain said measurement data.

17. A method according to clause 16 comprising, performing said method inline as part of a lithographic method.

18. A method according to clause 17, further comprising: exposing said at least one target onto a substrate; performing said measuring step; and using said corrected parameter of interest value or a parameter of interest value corresponding to the preferred illumination profile in correcting a subsequent exposing step on a subsequent substrate.

19. A computer program comprising program instructions operable to perform the method of any of clauses 1 to 12, when run on a suitable apparatus.

20. A non-transient computer program carrier comprising the computer program of clause 19.

21. A processing arrangement comprising:
a computer program carrier comprising the computer program of clause 20; and
a processor operable to run said computer program.

22. A metrology device comprising the processing arrangement of clause 21.

23. A metrology device according to clause 22, comprising: imaging optics for capturing scattered radiation from said target; and a detector for detecting the scattered radiation to obtain a measured image of the target.

24. The metrology device of clause 22 or 23, being a scatterometer.

25. The metrology device of clause 22 or 23, being a dark-field holographic microscope.

26. The metrology device of any of clauses 22 to 25, being operable to perform the method of clause 16 or 17.

27. A lithocell comprising: the metrology device of any of clauses 22 to 26; and a lithographic apparatus.

28. The lithocell of clause 27, being operable to perform the method of clause 18.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). The term “metrology apparatus” may also refer to an inspection apparatus or an inspection system. E.g. the inspection apparatus that comprises an embodiment of the invention may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed. Further, pitch P of the metrology targets may be close to the resolution limit of the optical system of the scatterometer or may be smaller, but may be much larger than the dimension of typical product features made by lithographic process in the target portions C. In practice the lines and/or spaces of the overlay gratings within the target structures may be made to include smaller structures similar in dimension to the product features.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-13. (canceled)

14. A metrology method comprising:
obtaining measurement data relating to measurement of at least one target using two or more different illumination profiles;
determining, from the measurement data, a respective parameter of interest value for a parameter of interest for each of the two or more different illumination profiles,
determining, from the measurement data, a respective measurement parameter deviation value for each of the two or more different illumination profiles, the measurement parameter deviation value describing a deviation in a measurement parameter with respect to a measurement parameter value attributed to a region of interest of the target or a sub-target thereof;
determining a relationship for the target between the parameter of interest values and the measurement parameter deviation values; and
determining one or both of a corrected parameter of interest value and a preferred illumination profile from the relationship.

15. The method of claim 14, comprising determining the preferred illumination profile as the illumination profile that corresponds to the lowest measurement parameter deviation for the target.

16. The method of claim 14, wherein the step of determining a relationship comprises fitting a model relating the parameter of interest values and the measurement parameter deviation values.

17. The method of claim 16, wherein the model comprises a linear model.

18. The method of claim 14, wherein the measurement parameter deviation value describes an extremum deviation in a measurement parameter with respect to a measurement parameter value attributed to a region of interest of the target or a sub-target thereof.

19. The method of claim 14, comprising determining the corrected parameter of interest value as the parameter of interest value corresponding to a zero measurement parameter deviation value according to the relationship.

20. The method of claim 14, wherein the measurement parameter deviation values are determined from regions of detected measurement images outside of the regions of interest.

21. The method of claim 14, wherein the measurement parameter deviation values are determined from one or more edges of the target or one or more sub-targets thereof.

22. The method of claim 14, wherein the target comprises one or more sub-targets per measurement direction, and the method is performed per measurement direction to obtain a corrected parameter of interest value and/or a preferred illumination profile per measurement direction.

23. The method of claim 14, wherein the number of illumination profiles used per target is more than three.

24. The method of claim 14, wherein the number of illumination profiles used per target is more than five.

25. The method as of claim 14, wherein the measurement parameter value attributed to a region of interest of the target or a sub-target thereof comprises an average measurement parameter value for the region of interest.

26. The method of claim 14, wherein the measurement parameter is intensity, diffraction efficiency or amplitude.

27. The method of claim 14, wherein the parameter of interest is overlay or focus.

28. The method of claim 14, wherein the measurement parameter deviation for the target comprises the measurement parameter deviation value having the greatest magnitude over different sub-targets of the target and/or different diffraction orders scattered by the target or sub-targets.

29. The method of claim 14, comprising measuring the at least one target to obtain the measurement data.

30. The method of claim 29 comprising, performing the method inline as part of a lithographic method.

31. The method of claim 30, further comprising:
exposing the at least one target onto a substrate;
performing the measuring step; and
using the corrected parameter of interest value or a parameter of interest value corresponding to the preferred illumination profile in correcting a subsequent exposing step on a subsequent substrate.

32. A non-transitory computer program product comprising program instructions operable to perform the method of claim 14, when run on a suitable apparatus.

33. A processing arrangement comprising:
a computer program carrier comprising the non-transitory computer program product of claim 32; and
a processor operable to run the program instructions.
